(19) United States
(12) Patent Application Publication
(10) Pub. No.: US 2019/0259893 A1
(43) Pub. Date: Aug. 22, 2019

(54) SOLAR BATTERY MODULE

(71) Applicant: TOYOTA JIDOSHA KABUSHIKI KAISHA, Toyota-shi,Aichi (JP)

(72) Inventors: Kazutaka KIMURA, Mishima-shi (JP); Hiroyuki OHBA, Suntou-gun (JP); Yuki KUDO, Susono-shi (JP); Shoichi IWAMOTO, Izunokuni-shi (JP)

(73) Assignee: TOYOTA JIDOSHA KABUSHIKI KAISHA, Toyota-shi, Aichi (JP)

(21) Appl. No.: 15/781,554

(22) PCT Filed: Dec. 19, 2016
(86) PCT No.: PCT/JP2016/087856

§ 371 Date: Jun. 5, 2018

(30) Foreign Application Priority Data
Dec. 24, 2015 (JP) 2015-252430

(51) Int. Cl. H01L 31/049; H01L 31/05; H01L 31/048; B32B 27/08

(52) U.S. Cl. CPC H01L 31/049; H01L 31/0512; B32B 2457/12; B32B 27/08; H01L 31/0481

(57) ABSTRACT

A solar battery module including: a solar battery cell; a surface layer that is made of a resin; a sealing layer having an upper portion sealing layer that seals an upper portion of the solar battery cell, and a lower portion sealing layer that seals a lower portion of the solar battery cell; and a back layer having a first metal layer made of a metal having a linear expansion coefficient lower than that of the resin constituting the surface layer, a foamed layer made of a foamed resin, and a second metal layer made of a metal having a linear expansion coefficient lower than that of the resin constituting the surface layer.

### TECHNICAL FIELD

The present invention relates to a solar battery module.

### BACKGROUND ART

As back materials for protecting sealing layers in solar battery modules, it is studied to use composite plates in which foamed resins are sandwiched between metals.

For example, a vehicle surface member having a solar battery device connected to a support layer manufactured by a method of manufacturing a composite light-weight structure and provided with an outer layer toward the outside of a vehicle is disclosed, and it is also disclosed that the composite light-weight structure for the support layer is formed into a sandwich structure in which a particularly lightweight layer such as a foam is disposed between a lower outer layer and an upper outer layer of plastic or lightweight metal (see, for example, Japanese National-Phase Publication (JP-A) No. 2011-530444).

A solar battery module in which a solar battery cell that generates electric power by sunlight is disposed on the front surface of a metal resin composite plate is disclosed, and it is also disclosed that the weight of a solar battery module is reduced by forming bubbles in a resin plate constituting a metal resin composite plate (see, for example, Japanese Patent Application Laid-Open (JP-A) No. 2004-14556).

### SUMMARY OF INVENTION

### Problems to be Solved by the Invention

When a sandwich composite plate using a foamed resin such as a composite light-weight structure or a metal resin composite plate described in JP-A No. 2011-530444 or JP-A No. 2004-14556 is used, the foamed resin is soft and has low strength, and therefore, the impact resistance against falling objects is not sufficient and the solar battery cell is liable to be broken, which is problematic.

One aspect of the invention has been made in view of the above conventional problems, and an object of the aspect of the invention is to provide a solar battery module that is excellent in impact resistance against falling objects and in which damage to a solar battery cell is suppressed.

### Means for Solving the Problems

The solar battery module of the first aspect is a solar battery module including: a solar battery cell; a surface layer that is disposed on a sunlight incident side of the solar battery module and is made of a resin; a sealing layer that is disposed on a side opposite to the sunlight incident side and that seals the solar battery cell, the sealing layer having, in a thickness direction, an upper portion sealing layer that seals an upper portion of the solar battery cell, which is on the sunlight incident side, and a lower portion sealing layer that seals a lower portion of the solar battery cell; and a back layer that is disposed on a side opposite to the side on which the surface layer and the sealing layer are disposed, and that has a first metal layer made of a metal having a linear expansion coefficient lower than that of the resin constituting the surface layer, a foamed layer made of a foamed resin, and a second metal layer disposed on a side opposite to the side on which the sealing layer and the first metal layer are disposed in such a manner to sandwich the foamed layer together with the first metal layer, the second metal layer being made of a metal having a linear expansion coefficient lower than that of the resin constituting the surface layer, wherein: a Young's modulus of an upper portion sealing material constituting the upper portion sealing layer is from 5 MPa to 20 MPa, and a Young's modulus of a lower portion sealing material constituting the lower portion sealing layer is 100 MPa or more, and a thickness t₁ (unit: mm, t₁≥0.15) of the first metal layer and a thickness t₂ (unit: mm, t₂≥0.5) of the upper portion sealing layer satisfy the relationships of the following Formulas (1) to (5):

t₂≥2.3(t₁=0.15) (1)

t₂≥22.333t₁²−15.817t₁+4.17(0.15<t₁<0.3) (2)

t₂≥−2.1165t₁+2.0699(0.3≤t₁≤0.7) (3)

t₂≥−0.5t₁+0.95(0.7<t₁<0.9) (4)

t₂=0.5(t₁≥0.9) (5).

According to the above configuration, even when a foamed resin that is soft and has low strength is disposed as a foamed layer, the thickness t₁ of the first metal layer and the thickness t₂ of the upper portion sealing layer satisfy the relationships of the above Formulas (1) to (5), and therefore, it is possible to provide a solar battery module that is excellent in impact resistance against falling objects and in which damage of the solar battery cell is suppressed.

In the solar battery module of the second aspect, the foamed resin constituting the foamed layer is at least one resin selected from the group consisting of a polypropylene resin, an acrylic resin, an acrylonitrile-butadiene-styrene copolymer resin, and a polyacetal resin.

According to the above configuration, the foamed resin is remelted at the time of high temperature lamination processing, and the foamed layer and the first metal layer and the second metal layer can be suitably fixed. Since the foamed resin has a relatively high softening temperature (for example, higher than that of polyethylene), it is possible to suitably suppress a foaming structure from being impaired by melting of the foamed layer in a module process.

In the solar battery module of the third aspect, an expansion ratio of the foamed resin constituting the foamed layer is five times or less.

According to the above configuration, it is possible to reduce the weight of the module while securing the impact resistance of the module.

In the solar battery module of the fourth aspect, the resin constituting the surface layer is a polycarbonate resin, and the metal constituting the first metal layer and the second metal layer is aluminum, an aluminum alloy, iron, or an iron alloy.

According to the above configuration, by using aluminum, an aluminum alloy, iron, or an iron alloy as the first metal layer and the second metal layer, a necessary rigidity for the module can be suitably secured.

In the solar battery module of the fifth aspect, a pillar structure covering at least a part of an outer peripheral end portion of the foamed layer is disposed.

According to the above configuration, a pillar structure covering at least a part of the outer peripheral end portion of the foamed layer that is soft and has low strength is disposed. Therefore, crushing at the outer peripheral end portion of the foamed layer can be suppressed.

### Effects of the Invention

According to one aspect of the invention, a solar battery module that is excellent in impact resistance against falling objects and in which damage to a solar battery cell is suppressed can be provided.

### BRIEF DESCRIPTION OF DRAWINGS

FIG. 1 is a cross-sectional view showing a schematic configuration of a solar battery module according to one embodiment of the invention.

FIG. 2A is a schematic configuration diagram showing a method of manufacturing a solar battery module according to the embodiment, and is a schematic configuration diagram showing a module before lamination.

FIG. 2B is a schematic configuration diagram showing a method of manufacturing a solar battery module according to the embodiment, and is a schematic configuration diagram showing a solar battery module after lamination.

FIG. 3A is a schematic diagram showing a module before lamination according to the embodiment.

FIG. 3B is a schematic view showing a solar battery module after lamination according to the embodiment.

FIG. 4A is a perspective view showing a back layer.

FIG. 4B is a cross-sectional view taken along line A-A in FIG. 4A.

FIG. 5A is a perspective view showing another back layer.

FIG. 5B is a cross-sectional view taken along line B-B in FIG. 5A.

FIG. 6 is a graph showing a condition satisfying the thickness t₁ of a first metal layer and the thickness t₂ of an upper portion sealing layer.

FIG. 7 is a graph showing a condition preferably satisfied by the thickness t₁ of a first metal layer and the thickness t₂ of an upper portion sealing layer.

FIG. 8 is an enlarged graph of FIG. 6 showing the results of FEM calculation.

FIG. 9 is a cross-sectional view showing a schematic configuration of a solar battery module to be compared according to the invention.

FIG. 10A is a schematic view showing a module before lamination in the object to be compared according to the invention.

FIG. 10B is a schematic view showing a solar battery module after lamination in the object to be compared according to the invention.

### DESCRIPTION OF EMBODIMENTS

Embodiments of the solar battery module of the invention will now be described with reference to the drawings. The sizes of members in each drawing are conceptual, and the relative relationship of the sizes between the members is not limited thereto. The same reference numerals are given to members having substantially the same functions throughout the drawings, and redundant explanation may be omitted.

[Solar Battery Module]

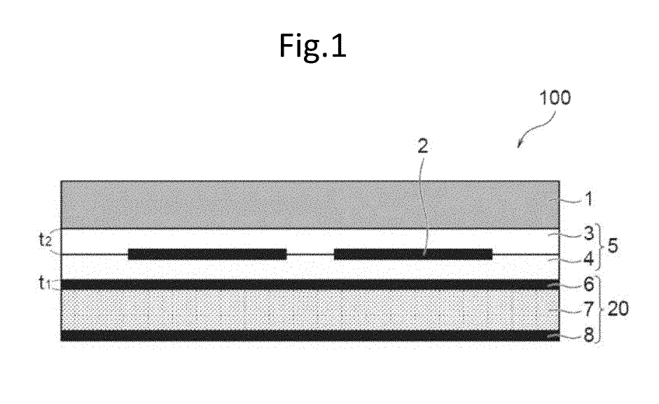

FIG. 1 is a cross-sectional view showing a schematic configuration of a solar battery module according to one embodiment of the invention. A solar battery module 100 according to the embodiment includes: a solar battery cell 2; a surface layer 1 that is disposed on the sunlight incident side and is made of a resin; a sealing layer 5 having an upper portion sealing layer 3 and a lower portion sealing layer 4 and sealing the solar battery cell 2; and a back layer 20 having a first metal layer 6 that is disposed on a side opposite to the side on which the surface layer 1 and the sealing layer 5 are disposed, and that is made of a metal having a linear expansion coefficient lower than that of the resin constituting the surface layer 1, a foamed layer 7 made of a foamed resin, and a second metal layer 8 that is disposed in such a manner to sandwich the foamed layer 7 together with the first metal layer 6, and that is made of a metal having a linear expansion coefficient lower than that of the resin constituting the surface layer 1. Further, in the solar battery module 100, a Young's modulus of a upper portion sealing material constituting the upper portion sealing layer 3 is from 5 MPa to 20 MPa, and a Young's modulus of a lower portion sealing material constituting the lower portion sealing layer 4 is 100 MPa or more, and a thickness t₁ (unit: mm, t₁≥0.15) of the first metal layer 6 and a thickness t₂ (unit: mm, t₂≥0.5) of the upper portion sealing layer 3 satisfy the relationships of the following Formulas (1) to (5):

t₂≥2.3(t₁=0.15) (1)

t₂≥22.333t₁²−15.817t₁+4.17(0.15<t₁<0.3) (2)

t₂≥−2.1165t₁+2.0699(0.3≤t₁≤0.7) (3)

t₂≥−0.5t₁+0.95(0.7<t₁<0.9) (4)

t₂=0.5(t₁≥0.9) (5).

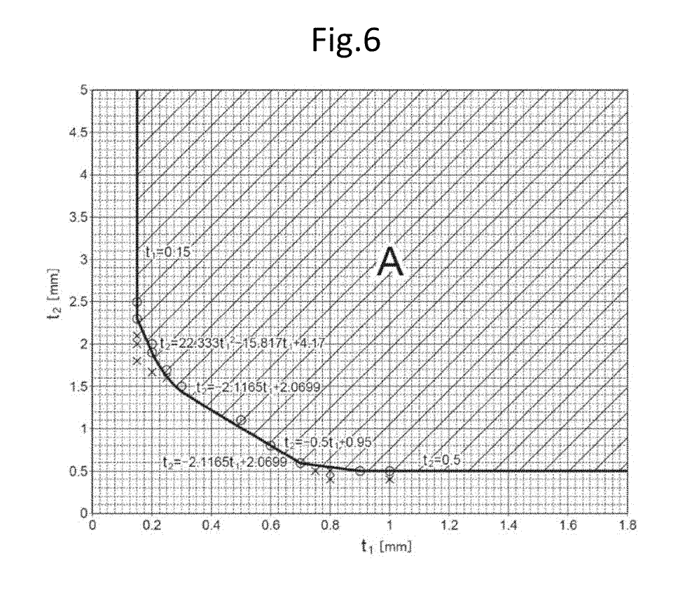

In the solar battery module 100 according to the embodiment, even when a foamed resin that is soft and has low strength is disposed as a foamed layer, the thickness t₁ of the first metal layer and the thickness t₂ of the upper portion sealing layer satisfy the relationships of the above Formulas (1) to (5), and therefore, impact resistance against falling objects is excellent and damage of the solar battery cell is suppressed. The region of t₁ and t₂ satisfying the above Formulas (1) to (5) represents the region A shown in the graph of FIG. 6.

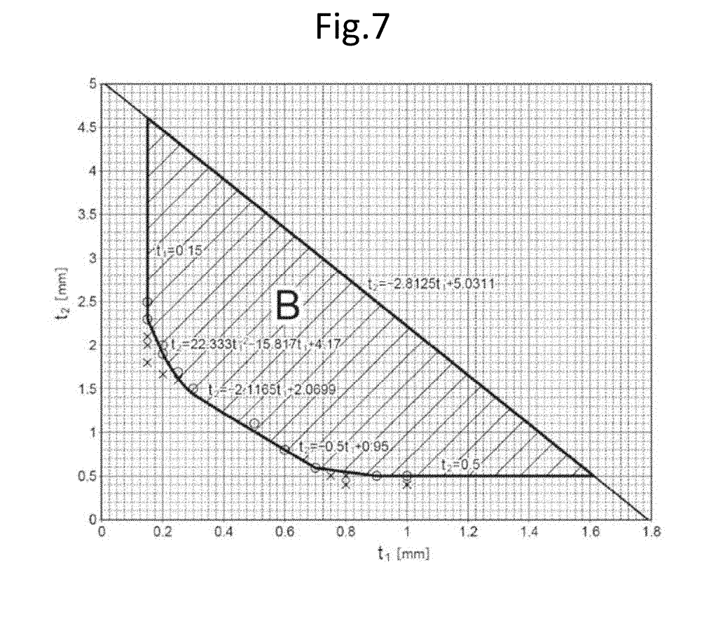

In the solar battery module 100 according to the embodiment, the upper limit values of t₁ and t₂ are not particularly limited as long as they satisfy Formulas (1) to (5), and it is preferable to satisfy the following Formulas (1)′, (2) to (4), the following Formula (5)′ and the following Formula (6) from the viewpoint of reducing the weight of the solar battery module 100. A region of t₁ and t₂ satisfying the above Formulas (1)′, (2) to (4), the following Formulas (5)′ and (6) represents the regions B shown in the graph of FIG. 7:

2.3≤t₂≤4.609(t₁=0.15) (1)′

t₂=0.5(0.9≤t₁≤1.611) (5)′

t₂≤−2.8125t₁+5.0311(t₁>0.15and t₂>0.5) (6).

Each layer constituting the solar battery module 100 will now be described.

The solar battery module 100 includes a surface layer 1. The surface layer 1 is disposed on a sunlight incident side (or a light receiving surface side of the solar battery cell 2) and is made of a resin.

The surface layer 1 is made of a resin having optical transparency and is a layer for protecting the solar battery cell 2 from erosion due to physical shock, rain, gas or the like. The resin constituting the surface layer 1 is not particularly limited as long as the resin can transmit sunlight, and a conventionally known resin can be used.

Examples of the resin constituting the surface layer 1 include a polycarbonate (PC) resin, a polymethyl methacrylate (PMMA) resin, a polyethylene (PE) resin, a polypropylene (PP) resin, a polystyrene (PS) resin, an acrylonitrile-styrene copolymer (AS) resin, an acrylonitrile-butadiene-styrene copolymer (ABS) resin, a polyethylene terephthalate (PET) resin, a polyethylene naphthalate (PEN) resin, a polyvinyl chloride (PVC) resin, a polyvinylidene chloride (PVDC) resin, and a polyamide (PA) resin.

Among these, a polycarbonate resin and a polymethyl methacrylate resin are preferable, and a polycarbonate resin is more preferable.

A variety of additives may be added to the resin constituting the surface layer 1. Examples of the additives include an inorganic fiber such as glass or alumina, an organic fiber such as aramid, polyether ether ketone, or cellulose, an inorganic filler such as silica, clay, alumina, aluminum hydroxide, or magnesium hydroxide, an ultraviolet absorber, an infrared absorber, and an antistatic agent.

The thickness of the surface layer 1 is set, if appropriate in consideration of the mechanical strength (especially rigidity), weight reduction, and the like of the solar battery module 100. In the embodiment, the thickness of the surface layer 1 is preferably from 0.1 mm to 2.0 mm, more preferably from 0.3 mm to 1.5 mm, and still more preferably from 0.5 mm to 1.0 mm.

The metal constituting the first metal layer 6 and the metal constituting the second metal layer 8 have a linear expansion coefficient lower than that of the resin constituting the surface layer 1. In other words, the surface layer 1 is made of a material having a linear expansion coefficient higher than that of the metal constituting the first metal layer 6 and that of the metal constituting the second metal layer 8. Herein, a linear expansion coefficient is a value measured in accordance with JIS R 1618: 2002.

The linear expansion coefficient of the resin constituting the surface layer 1 is, for example, preferably from 2.5×10⁻⁵K⁻¹ to 2.0×10⁻⁴K⁻¹, more preferably from 4.0×10⁻⁵K⁻¹ to 1.5×10⁻⁴K⁻¹, and still more preferably from 5.0×10⁻⁵K⁻¹ to 1.0×10⁻⁴K⁻¹.

The solar battery module 100 is disposed on the side opposite to the sunlight incident side on the surface layer 1 and is provided with a sealing layer 5 that seals the solar battery cell 2.

The solar battery cell 2 is not particularly limited, and a conventionally known solar battery cell can be used. As a specific example of the solar battery cell 2, any solar battery cell such as silicon type (single crystal silicon type, polycrystalline silicon type, microcrystalline silicon type, amorphous silicon type, or the like), compound semiconductor type (InGaAs type, GaAs type, CIGS type, CZTS type, or the like), a dye sensitizing type, or an organic thin film type is used. Among these, a silicon type solar battery cell is preferable, and a single crystal silicon type or polycrystalline silicon type solar battery cell is more preferable.

In the solar battery cell 2, the upper part and the lower part are sealed with an upper portion sealing material and a lower portion sealing material respectively. The upper portion sealing layer 3 for sealing the upper side of the solar battery cell 2 on which sunlight is incident and the lower portion sealing layer 4 for sealing the lower portion of the solar battery cell 2 are constituted by the upper portion sealing material and the lower portion sealing material, respectively, in the thickness direction. The sealing layer 5 for sealing the solar battery cell 2 is constituted by the upper portion sealing layer 3 and the lower portion sealing layer 4.

An upper portion sealing material constituting the upper portion sealing layer 3 sealing the upper portion of the solar battery cell 2 is not particularly limited as long as the material is a sealing material capable of transmitting sunlight and having a Young's modulus of from 5 MPa to 20 MPa, and a conventionally known sealing material can be used as the upper portion sealing material.

Herein, the Young's modulus is a value obtained by a tensile test at 25° C. by applying a tensile load to a plate-shaped test piece and calculating the displacement.

Specific examples of the material of the upper portion sealing material include a thermoplastic resin and a crosslinked resin, and examples thereof include an ethylene-vinyl acetate copolymer (EVA) resin.

A variety of additives may be added to the upper portion sealing material in order to improve adhesion, weather resistance, and the like. As the additive, for example, an adhesion improver such as a silane coupling agent, an ultraviolet absorber, an antioxidant, a discoloration inhibitor, or the like can be blended.

The thickness t₂ of the upper portion sealing layer 3 is set, if appropriate in consideration of the thickness of the solar battery cell 2, the type of the upper portion sealing material, and the like within the range satisfying the relationship of Formula (1). The thickness t₂ of the upper portion sealing layer 3 is preferably from 0.5 mm to 5.0 mm, more preferably from 0.5 mm to 2.0 mm, and still more preferably from 0.5 mm to 1.5 mm.

The lower portion sealing material constituting the lower portion sealing layer 4 sealing the lower portion of the solar battery cell 2 is not particularly limited as long as the material is a sealing material having a Young's modulus of 100 MPa or more, and a conventionally known sealing material can be used.

The Young's modulus of the lower portion sealing material constituting the lower portion sealing layer 4 is 100 MPa or more, and preferably 250 MPa or more. The Young's modulus of the lower portion sealing material is preferably 3,000 MPa or less, and more preferably 2,000 MPa or less.

The lower portion sealing material is preferably a resin having a softening temperature or a thermosetting temperature of 110° C. or higher.

Specific examples of the material of the lower portion sealing material include a thermoplastic resin and a crosslinked resin, and examples thereof include a polyolefin resin.

A variety of additives may be blended in the lower portion sealing material in order to improve adhesiveness, weather resistance, and the like. As the additive, for example, an adhesion improver such as a silane coupling agent, an ultraviolet absorber, an antioxidant, a discoloration inhibitor, or the like can be blended.

The thickness of the lower portion sealing layer 4 is set, if appropriate in consideration of the thickness of the solar battery cell 2, the type of the lower portion sealing material, and the like. The thickness of the lower portion sealing layer 4 is preferably from 0.2 mm to 1.2 mm, more preferably from 0.2 mm to 1.0 mm, and still more preferably from 0.2 mm to 0.8 mm.

The solar battery module 100 includes a back layer 20 having a first metal layer 6, a foamed layer 7, and a second metal layer 8. Each layer constituting the back layer 20 will now be described.

The solar battery module 100 includes the first metal layer 6. The first metal layer 6 is disposed on the side of the sealing layer 5 opposite to the side on which the surface layer 1 is disposed, and is made of a metal having a linear expansion coefficient lower than that of the resin constituting the surface layer 1.

The linear expansion coefficient of the metal constituting the first metal layer 6 may be any value as long as the value is lower than the linear expansion coefficient of the resin constituting the surface layer 1, and for example, the value is preferably from 5.0×10⁻⁶K⁻¹ to 5.0×10⁻⁵K⁻¹, more preferably from 1.0×10⁻⁵K⁻¹ to 4.0×10⁻⁵K⁻¹, and still more preferably from 1.5×10⁻⁵K⁻¹ to 3.0×10⁻⁵K⁻¹.

The metal constituting the first metal layer 6 is not particularly limited as long as the metal is a metal having a linear expansion coefficient lower than that of the resin constituting the surface layer 1, and examples thereof include aluminum, an aluminum alloy, iron, and an iron alloy from the viewpoint of appropriately securing necessary rigidity for the module, and among them, aluminum or an aluminum alloy is preferable.

The thickness t₁ of the first metal layer 6 is set, if appropriate in consideration of the mechanical strength (especially rigidity), weight reduction, and the like of the solar battery module 100 within a range satisfying the relationship of Formula (1). In the embodiment, the thickness of the first metal layer 6 is preferably from 0.1 mm to 1.6 mm, more preferably from 0.1 mm to 1.0 mm, and still more preferably from 0.15 mm to 0.75 mm.

The solar battery module 100 includes a foamed layer 7. The foamed layer 7 is made of a foamed resin and is a layer sandwiched between the first metal layer 6 and the second metal layer 8.

By making the layer sandwiched between the first metal layer 6 and the second metal layer 8 a foamed layer 7 made of a foamed resin, it is possible to reduce the weight of a solar battery module. Since the strength of a foamed resin is usually low, when a foamed layer made of a foamed resin is provided in a solar battery module, the impact resistance against falling objects is not sufficient, and the solar battery cell is liable to be damaged, which is problematic. However, since the solar battery module 100 according to the embodiment satisfies the relationships of Formulas (1) to (5), it is possible to sufficiently ensure the impact resistance to the falling objects, thereby suppressing damage to the solar battery cell 2.

Further, by making the layer sandwiched between the first metal layer 6 and the second metal layer 8 the foamed layer 7 made of a foamed resin, the foamed layer 7 functions as a heat insulating layer. Therefore, a temperature difference can be generated between the first metal layer 6 and the second metal layer 8 during high temperature lamination processing of the solar battery module 100 described below. And by using the temperature difference generated between the first metal layer 6 and the second metal layer 8 during a high temperature lamination processing, it is possible to deform the entire solar battery module 100 in a direction protruding upward after cooling the solar battery module 100.

The expansion ratio of the foamed resin constituting the foamed layer 7 is, from the viewpoint of securing the impact resistance of the module and reducing the weight of the module, preferably five times or less, more preferably from two times to five times, and still more preferably from two times to three times. The expansion ratio is a value obtained by dividing the density of a resin before foaming by the density of a foamed resin.

The foamed resin constituting the foamed layer 7 is preferably at least one resin selected from the group consisting of a polypropylene resin, an acrylic resin, an acrylonitrile-butadiene-styrene copolymer resin, and a polyacetal resin, and among them, a polypropylene resin is more preferable.

When a polyurethane resin is used as the foaming resin constituting the foamed layer 7, there is a possibility that the polyurethane resin is not re-melted at the time of a high temperature lamination processing of the solar battery module 100 described below. For this reason, the foamed layer 7, the first metal layer 6, and the second metal layer 8 are unable to be fixed in a state where a temperature difference is generated between the first metal layer 6 and the second metal layer 8 at a high temperature, and there is a possibility that the solar battery module 100 deformed in a convex direction is unable to be manufactured by a high temperature lamination processing.

When a polyethylene resin is used as the foaming resin constituting the foamed layer 7, since the polyethylene resin has a low softening temperature, the polyethylene resin melts at a module process of the solar battery module 100 (at a temperature of from 120° C. to 140° C.), which may impair the foamed structure.

The thickness of the foamed layer 7 is set, if appropriate in consideration of the mechanical strength, weight reduction, and the like of the solar battery module 100. In the embodiment, the thickness of the foamed layer 7 is preferably from 1.0 mm to 5.0 mm, more preferably from 1.2 mm to 3.0 mm, and still more preferably from 1.5 mm to 2.0 mm.

The solar battery module 100 includes a second metal layer 8. The second metal layer 8 is disposed in such a manner to sandwich the foamed layer 7 together with the first metal layer 6, and is made of a metal having a linear expansion coefficient lower than that of the resin constituting the surface layer 1.

The linear expansion coefficient of the metal constituting the second metal layer 8 may be any value as long as the value is lower than the linear expansion coefficient of the resin constituting the surface layer 1, and for example, the value is preferably from 5.0×10⁻⁶K⁻¹ to 5.0×10⁻⁵K⁻¹, more preferably from 1.0×10⁻⁵K⁻¹ to 4.0×10⁻⁵K⁻¹, and still more preferably from 1.5×10⁻⁵K⁻¹ to 3.0×10⁻⁵K⁻¹.

The metal constituting the second metal layer 8 is not particularly limited as long as the metal is a metal having a linear expansion coefficient lower than that of the resin constituting the surface layer 1, and examples thereof include aluminum, an aluminum alloy, iron, and an iron alloy, and among them, aluminum or an aluminum alloy is preferable.

The metal constituting the second metal layer 8 is preferably the same as the metal constituting the first metal layer 6. In this case, examples of the metal constituting the first metal layer 6 and the second metal layer 8 include aluminum, an aluminum alloy, iron, and an iron alloy, and among them, aluminum or an aluminum alloy is preferable.

The thickness of the second metal layer 8 is set, if appropriate in consideration of the mechanical strength (especially rigidity), weight reduction, and the like of the solar battery module 100. In the embodiment, the thickness of the second metal layer 8 is preferably from 0.1 mm to 1.0 mm, more preferably from 0.2 mm to 0.8 mm and still more preferably from 0.3 mm to 0.6 mm.

[Manufacturing Method of Solar Battery Module]

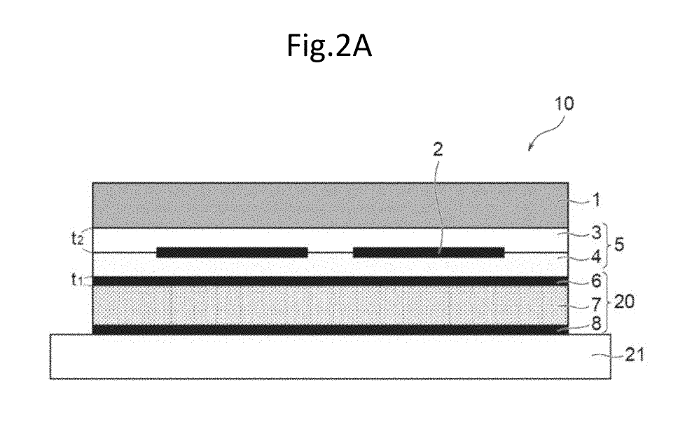

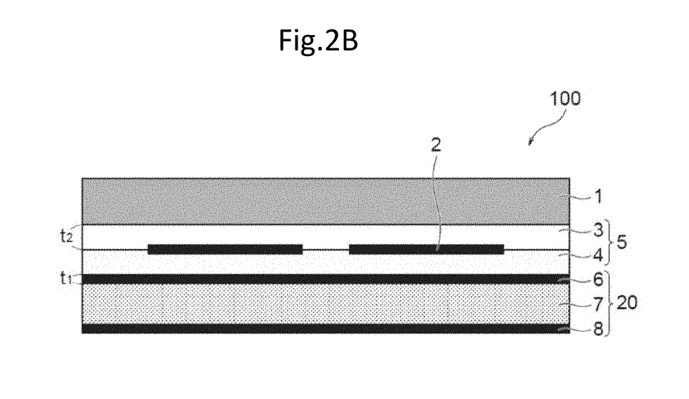

Hereinafter, a method of manufacturing the solar battery module 100 according to the embodiment will be described with reference to FIGS. 2A and 2B. FIGS. 2A and 2B are schematic configuration diagrams showing a method of manufacturing the solar battery module 100 according to the embodiment, FIG. 2A is a schematic configuration diagram showing the module 10 before lamination, and FIG. 2B is a schematic configuration diagram showing the solar battery module 100 after lamination.

First, as shown in FIG. 2A, the module 10 before lamination formed by layering a back layer 20 having the second metal layer 8, the foamed layer 7 and the first metal layer 6 in this order as seen from the hot plate 21, the lower portion sealing layer 4, the solar battery cell 2, the upper portion sealing layer 3, and the surface layer 1 in this order is placed on a hot plate 21 provided in a vacuum laminator device (not illustrated).

After performing vacuum lamination according to the type of the upper portion sealing material (for example, EVA) constituting the upper portion sealing layer 3, a second cure (curing acceleration) is performed in a high temperature furnace (for example, 120° C.) to manufacture a solar battery module 100 as shown in FIG. 2B.

In the manufacturing method of the solar battery module 100 according to the embodiment, by making the layer sandwiched between the first metal layer 6 and the second metal layer 8 the foamed layer 7 made of a foamed resin, the foamed layer 7 functions as a heat insulating layer. For this reason, a temperature difference can be generated between the first metal layer 6 and the second metal layer 8 during the high temperature lamination processing of the solar battery module 100.

For example, when the temperature of the hot plate 21 is adjusted to about 140° C., the temperature of the second metal layer 8 in contact with the hot plate 21 becomes about the same temperature (about 140° C.) as that of the hot plate 21. Since the foamed layer 7 functions as a heat insulating layer, the temperature of the first metal layer 6 becomes lower than the temperature of the second metal layer 8 (for example, about 120° C.). By this, when the first metal layer 6 and the second metal layer 8 are made of the same metal, by cooling after completion of high temperature lamination processing, the second metal layer 8 shrinks more than the first metal layer 6, the entire solar battery module 100 is deformed in a direction protruding upward, a surface tension feeling (warping) is maintained, and the appearance can be improved.

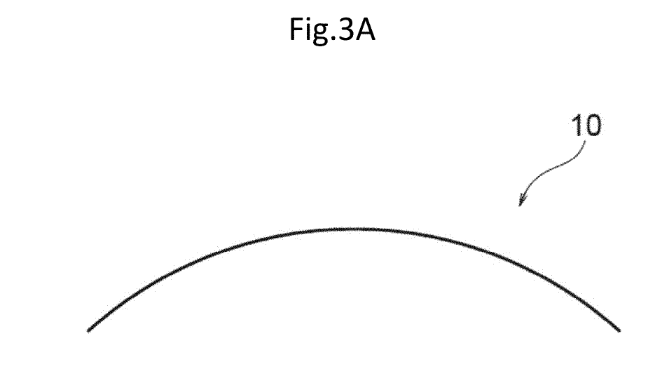

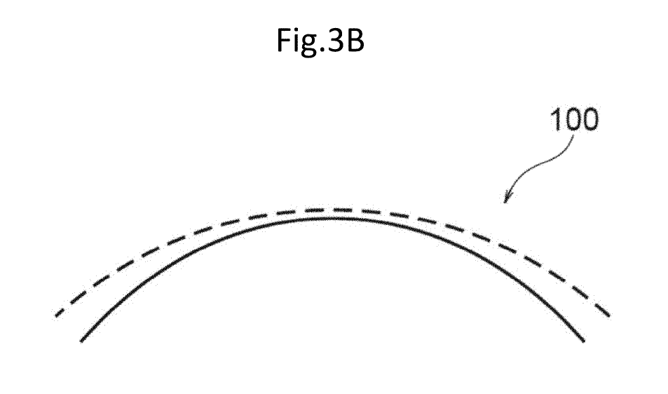

Therefore, as shown in FIG. 3A, when the module 10 before lamination has a curved surface shape in a direction protruding upward, deformation in a direction protruding upward is generated and the radius of curvature is increased as shown in FIG. 3B by performing high temperature lamination processing. By this, the surface tension feeling of the solar battery module 100 is maintained, and the appearance can be improved.

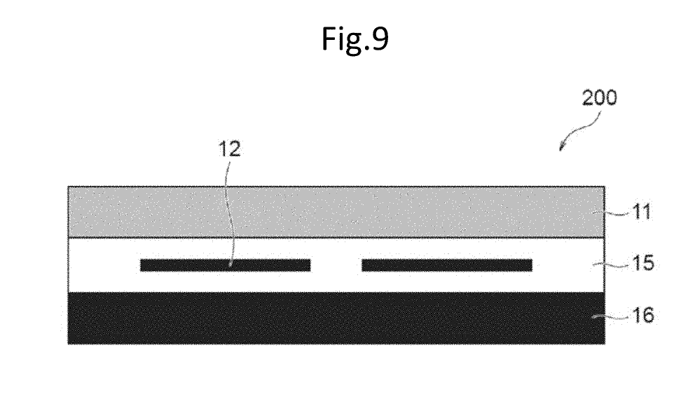

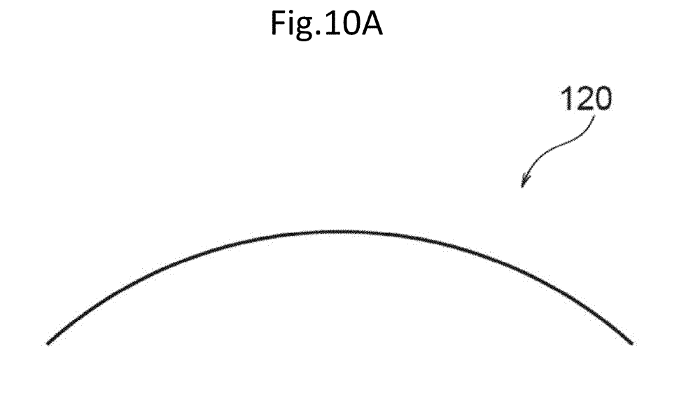

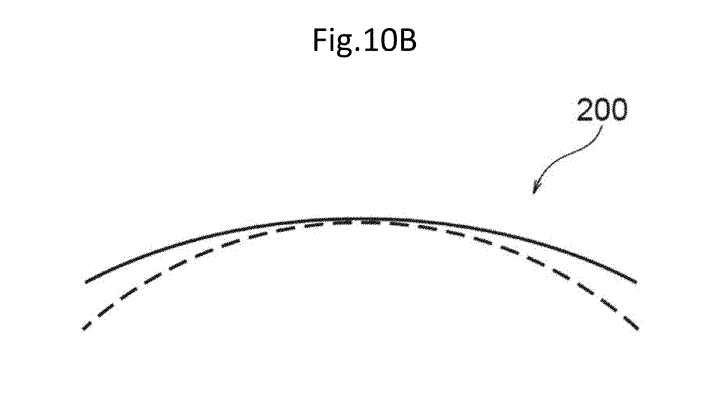

The solar battery module to be compared according to the present invention will be described with reference to FIGS. 9, 10A, and 10B. FIG. 9 is a cross-sectional view showing a schematic configuration of a solar battery module to be compared according to the invention, FIG. 10A is a schematic view showing a module before lamination in an object to be compared of the invention, and FIG. 10B is a schematic view showing a solar battery module after lamination in an object to be compared of the invention.

In the solar battery module 200 including the surface layer 11 made of a resin as shown in FIG. 9, the sealing layer 15 sealing the solar battery cell 12, and the metal layer 16, the surface layer 11, the solar battery cell 12, and the metal layer 16 have different linear expansion coefficients, and in particular, the surface layer 11 has a higher linear expansion coefficient than that of the metal layer 16.

Therefore, when the solar battery module 200 is manufactured by high temperature lamination processing of the module 120 before lamination in which the metal layer 16, the sealing layer 15, and the surface layer 11 are layered in this order, a deformation of the solar battery module as a whole in a direction protruding upward is inhibited by the difference in linear expansion coefficient between the surface layer 11 and the metal layer 16, and the lack of surface tension feeling and the appearance deteriorate, which is problematic.

Therefore, as shown in FIG. 10A, when the module 120 before lamination has a curved shape in a direction protruding upward, deformation in a direction protruding upward is inhibited, and the radius of curvature becomes small as shown in FIG. 10B by performing high temperature lamination processing. As a result, the surface tension feeling of the solar battery module 200 is lacked, and the appearance deteriorates.

On the other hand, by manufacturing the solar battery module 100 by the manufacturing method according to the embodiment, it is possible to maintain the surface tension feeling and improve the appearance as described above.

<Modified Example of Back Layer>

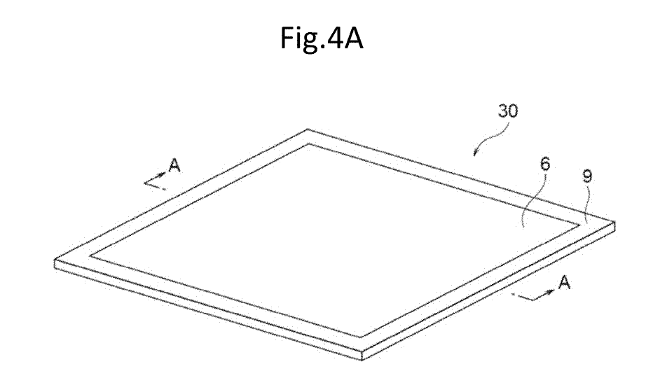

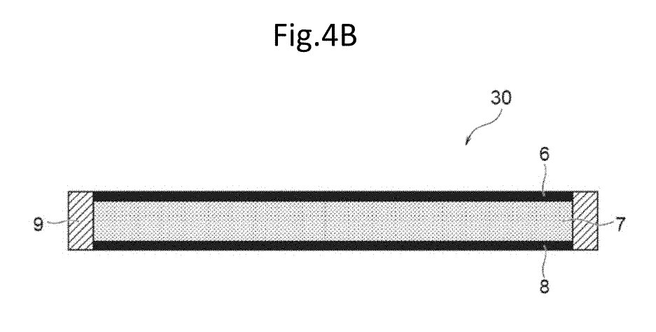

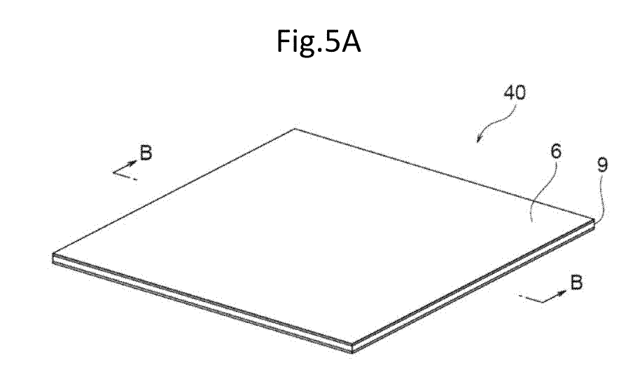

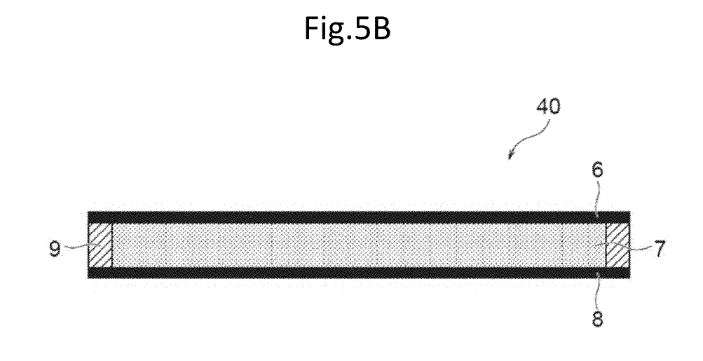

Hereinafter, modified example of the back layer including the first metal layer 6, the foamed layer 7, and the second metal layer 8 will now be described with reference to FIGS. 4A, 4B, 5A, and 5B. FIG. 4A is a perspective view showing the back layer 30, and FIG. 4B is a cross-sectional view taken along line A-A in FIG. 4A. FIG. 5A is a perspective view showing the back layer 40, and FIG. 5B is a cross-sectional view taken along line B-B in FIG. 5A. For convenience of explanation, in FIGS. 4A, 4B, 5A and 5B, structures other than the back layer including the first metal layer 6, the foamed layer 7, and the second metal layer 8 in the solar battery module 100, or, the surface layer 1 and the sealing layer 5 are omitted.

As shown in FIGS. 4A, 4B, 5A, and 5B, in the solar battery module 100 according to the embodiment, a honeycomb structure 9 (pillar structure) covering the outer peripheral end portion of the foamed layer 7 may be disposed. The honeycomb structure 9 may be a structure covering the outer peripheral end portion of the foamed layer 7 in a direction perpendicular to the thickness direction of the solar battery module 100, or may be a structure covering at least a part of the outer peripheral end portion of the foamed layer 7.

Although the foamed layer 7 made of a foamed resin is excellent in terms of being able to protect the solar battery cell 2 while achieving weight saving, since the foamed layer 7 is soft and has low strength, the outer peripheral end portion is liable to be crushed, and there is a possibility that the outer peripheral end portion of the foamed layer 7 is crushed when the module is manufactured, for example when mounting the module on a vehicle.

Therefore, by covering the outer peripheral end portion of the foamed layer 7 with the honeycomb structure 9, which is a highly rigid structure, crushing at the outer peripheral end portion of the foamed layer 7 can be suppressed.

When arranging the honeycomb structure 9 at the outer peripheral end portion of the foamed layer 7, as shown in FIGS. 4A and 4B, the back layer 30 in which the outer peripheral end portions of the first metal layer 6, the foamed layer 7, and the second metal layer 8 are covered with the honeycomb structure 9 may be used, and as shown in FIGS. 5A and 5B, the back layer 40 in which the honeycomb structure 9 covers the outer peripheral end portion of the foamed layer 7, and the foamed layer 7 and the honeycomb structure 9 are sandwiched between the first metal layer 6 and the second metal layer 8 in the thickness direction may be used.

It is preferable that the honeycomb structure is made of at least one selected from the group consisting of metal, paper, and resin.

### EXAMPLES

Hereinafter, the invention will be described more specifically with reference to Examples, but the invention is not limited by these Examples.

<Calculation of Cell Stress in Solar Battery Module>

Regarding a solar battery module including a solar battery cell 2 and layer structures (a surface layer 1, an upper portion sealing layer 3, a lower portion sealing layer 4, a first metal layer 6, a foamed layer 7, and a second metal layer 8) shown in FIG. 1, the cell stress (maximum stress applied to the cell) was calculated by FEM (finite element method) calculation. In the FEM calculation, Abaqus 6.11 was used as software.

The thickness of the surface layer, the thickness and physical properties (rigidity) of the upper portion sealing layer, the thickness and physical properties of the lower portion sealing layer, the thickness of the first metal layer, the thickness and physical properties of the foamed layer, and the thickness of the second metal layer were used as parameters used for the FEM calculation. Then, the cell stress when each parameter was varied was determined by the FEM calculation.

<Extraction of High Sensitivity Parameters>

From the obtained cell stress values, parameters with high sensitivity among the parameters used for the FEM calculation were extracted. Specifically, with other parameters kept constant, high sensitivity parameters were extracted from the change rate of the cell stress when a specific parameter was varied.

As a result, it was found that a high sensitivity parameter, or a parameter having a high influence on the cell stress was the thickness t₁ of the first metal layer that was the upper portion metal layer and the thickness t₂ of the upper portion sealing layer.

<Relationship Between Cell Stress and High Sensitivity Parameter>

The relationship between the cell stress and the thickness t₁ of the first metal layer and the thickness t₂ of the upper portion sealing layer that was a highly sensitive parameter was examined. Specifically, from a change in the cell stress when the thickness t₁ of the first metal layer was varied and a change in the cell stress when the thickness t₂ of the upper portion sealing layer was varied, the relationship between the thickness t₁ of the first metal layer and the thickness t₂ of the upper portion sealing layer when the cell stress (allowable stress) to be criteria was 367.6 MPa was obtained. As a result, it was found that when t₁ and t₂ were around t₁=0.6 and t₂=0.8, the cell stress was 367.6 MPa at t₂=−2.1165 t₁+2.0699. Therefore, when t₁ and t₂ were around t₁=0.6 and t₂=0.8, it was inferred that the cell stress was 367.6 MPa or less at t₂≥−2.1165 t₁+2.0699.

In determining the relationship between the cell stress and the high sensitivity parameter, each layer constituting the solar battery cell and the solar battery module was set as follows.

| | |
|---|---|
| Surface layer | Polycarbonate resin (thickness: 0.8 mm, |
| | linear expansion coefficient: 7.0 × 10⁻⁵K⁻¹) |
| Solar battery cell | Single crystal silicon (thickness: 0.2 mm) |
| Upper portion sealing layer | EVA resin (thickness: t₂ mm) |
| Lower portion sealing layer | Polyolefin resin (thickness: 0.4 mm) |
| First metal layer | Aluminum alloy (thickness: t₁ mm, linear |
| | expansion coefficient: 2.4 × 10⁻⁵K⁻¹) |
| Foamed layer | Polypropylene resin (thickness: 1.5 mm) |
| Second metal layer | Aluminum alloy (thickness: 0.3 mm, linear |
| | expansion coefficient: 2.4 × 10⁻⁵K⁻¹) |

Next, under the condition of t₂=−2.1165 t₁+2.0699, in order to calculate the lower limit values of t₁ and t₂ satisfying the cell stress of 367.6 MPa respectively, t₁ and t₂ were varied within the range satisfying t₂=−2.1165t₁+2.0699, and the FEM calculation was carried out. As a result, the lower limit of t₁ was 0.3 mm and the lower limit of t₂ was 0.6 mm.

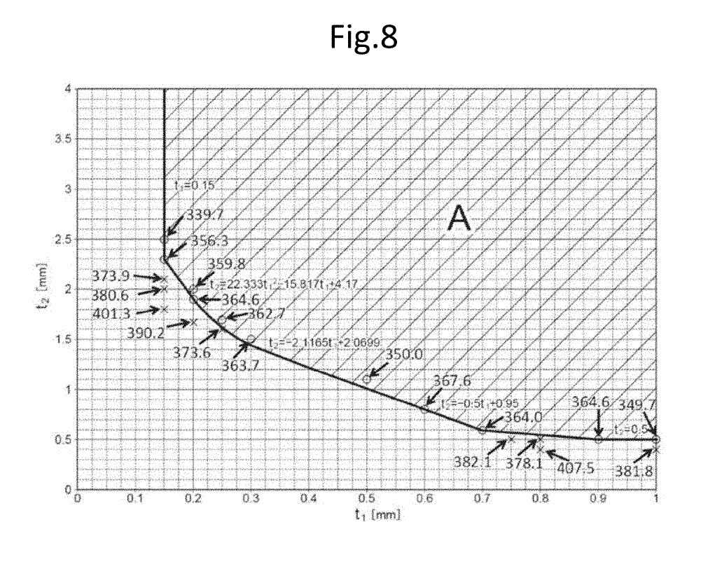

Further, in order to obtain the conditions of t₁ and t₂ at which the cell stress became 367.6 MPa or less when t₁ was 0.3 mm or less and the conditions of t₁ and t₂ at which the cell stress became the criteria of 367.6 MPa or less when t₂ was 0.6 mm or less, the cell stress when t₁ and t₂ were varied around the lower limit of t₁ and around the lower limit of t₂ were calculated by the FEM calculation. The results are shown in FIGS. 6 and 8. In FIGS. 6 and 8, calculation results where the cell stress was 367.6 MPa or less are circled, and the calculation results with the cell stress exceeding 367.6 MPa are marked X. FIG. 8 is an enlarged graph of FIG. 6, and numerical values of the cell stress calculated by the FEM calculation are shown on the graph.

From the results in FIGS. 6 and 8, it was found that the conditions of t₁ and t₂ at which the cell stress became the criteria of 367.6 MPa or less satisfied the following Formulas (1) to (5):

t₂≥2.3(t₁=0.15) (1)

t₂≥22.333t₁²−15.817t₁+4.17(0.15<t₁<0.3) (2)

t₂≥−2.1165t₁+2.0699(0.3≤t₁≤0.7) (3)

t₂≥−0.5t₁+0.95(0.7<t₁<0.9) (4)

t₂=0.5(t₁≥0.9) (5).

### Example 1

### <Fabrication of Solar Battery Module>

Next, based on the result of the FEM calculation, a solar battery module was fabricated and tested for the impact resistance.

The solar battery module according to Example 1 includes a solar battery cell 2 and layer structures (a surface layer 1, an upper portion sealing layer 3, a lower portion sealing layer 4, a first metal layer 6, a foamed layer 7, and a second metal layer 8) shown in FIG. 1. In the embodiment, the solar battery cell and each layer in the solar battery module are composed of the following materials, and the thicknesses of the solar battery cell and each layer are as follows.

| | |
|---|---|
| Surface layer | polycarbonate resin (thickness: 0.8 mm, |
| | linear expansion coefficient: 7.0 × 10⁻⁵K⁻¹) |
| Solar battery cell | single crystal silicon (thickness: 0.2 mm) |
| Upper portion sealing layer | EVA resin (thickness: 0.8 mm) |
| Lower portion sealing layer | polyolefin resin (thickness: 0.4 mm) |
| First metal layer | aluminum alloy (thickness: 0.6 mm, linear |
| | expansion coefficient: 2.4 × 10⁻⁵K⁻¹) |
| Foamed layer | polypropylene resin (thickness: 1.5 mm) |
| Second metal layer | aluminum alloy (thickness: 0.3 mm, linear |
| | expansion coefficient: 2.4 × 10⁻⁵K⁻¹) |

The solar battery module according to the Example was fabricated as follows.

First, a module before lamination was formed by layering a back layer having the second metal layer, the foamed layer and the first metal layer in this order as seen from the hot plate, the lower portion sealing layer, the solar battery cell, the upper portion sealing layer, and the surface layer in this order is placed on a hot plate provided in a vacuum laminator device. The hot plate was heated to 140° C. and the module before lamination was subjected to high temperature lamination processing (heating time in vacuum for 15 minutes, pressing time at 100 kPa for 30 minutes), and then second cure (curing acceleration) was performed in a high temperature furnace at 120° C. In such a manner, a solar battery module was fabricated.

In the solar battery module according to Example 1, the cell stress is 367.6 MPa (cell stress to be criteria), and the thickness t₁ of the first metal layer is 0.6 mm and the thickness t₂ of the upper portion sealing layer is 0.8 mm. In the solar battery module according to Example 1, the values of the left side and the right side in the following Formula (3) are both 0.8, and therefore, the relationship of the following Formula (3) is satisfied.

t₂≥−2.1165t₁+2.0699(0.3≤t₁≤0.7) (3)

### Example 2

The solar battery module according to Example 2 includes a solar battery cell 2 and layer structures (a surface layer 1, an upper portion sealing layer 3, a lower portion sealing layer 4, a first metal layer 6, a foamed layer 7, and a second metal layer 8) shown in FIG. 1. In the embodiment, the solar battery cell and each layer in the solar battery module are composed of the following materials, and the thicknesses of the solar battery cell and each layer are as follows.

| | |
|---|---|
| Surface layer | polycarbonate resin (thickness: 0.8 mm, |
| | linear expansion coefficient: 7.0 × 10⁻⁵K⁻¹) |
| Solar battery cell | single crystal silicon (thickness: 0.2 mm) |
| Upper portion sealing layer | EVA resin (thickness: 1.6 mm) |
| Lower portion sealing layer | polyolefin resin (thickness: 0.4 mm) |
| First metal layer | aluminum alloy (thickness: 0.3 mm, linear |
| | expansion coefficient: 2.4 × 10⁻⁵K⁻¹) |
| Foamed layer | polypropylene resin (thickness: 1.5 mm) |
| Second metal layer | aluminum alloy (thickness: 0.6 mm, linear |
| | expansion coefficient: 2.4 × 10⁻⁵K⁻¹) |

The solar battery module according to Example 2 was fabricated in a similar manner to Example 1. In the solar battery module according to Example 2, the cell stress is 363.7 MPa (cell stress to be criteria or less), and the thickness t₁ of the first metal layer is 0.3 mm and the thickness t₂ of the upper portion sealing layer is 1.6 mm. In the solar battery module according to Example 2, in the above-described Formula (3), the value of the left side is 1.6 and the right side is 1.43495, and therefore, the relationship of the above-described Formula (3) is satisfied.

### Comparative Example 1

A solar battery module was fabricated in a similar manner to Example 1 except that the thickness of the first metal layer was changed from 0.6 mm to 0.3 mm. In the solar battery module according to Comparative Example 1, the cell stress is over 367.6 MPa (cell stress to be criteria or less), and the thickness t₁ of the first metal layer is 0.3 mm and the thickness t₂ of the upper portion sealing layer is 0.8 mm. In the solar battery module according to Comparative Example 1, in the above-described Formula (3), the value of the left side is 0.8 and the right side is 1.43495, and therefore, the relationship of the above-described Formula (3) is not satisfied.

[Evaluation]

—Impact Resistance (Steel Ball Drop Test)—

For the fabricated solar battery modules according to Examples 1 and 2 and Comparative Example 1, a steel ball drop test was conducted. In the steel ball drop test, the fabricated solar battery module was fixed, and a crack of the solar battery module was evaluated when dropping a weight of 227 g from a height of 1 m. The evaluation criteria are as follows.

Qualified: No crack was found in a solar battery module.

Disqualified: A crack was found in a solar battery module.

Accordingly, the solar battery modules according to Examples 1 and 2 in which the cell stresses were 367.6 MPa and 363.7 MPa were excellent in impact resistance against falling objects, and the damage of the solar battery cell was suppressed. On the other hand, the solar battery module according to Comparative Example 1, in which the cell stress was over 367.6 MPa, had insufficient impact resistance against falling objects.

Here, also for a solar battery module with a cell stress of 367.6 MPa or less, it is presumed that impact resistance against falling objects is superior as in the solar battery modules according to Examples 1 and 2, and damage of the solar battery cell is suppressed. Therefore, it is presumed that when t₁ and t₂ are within the region shown in FIG. 6, or when t₁ and t₂ satisfy the above Formulas (1) to (5), a solar battery module excellent in impact resistance against falling objects and suppressed damage of a solar battery cell can be obtained.

### Examples 3 to 6

A solar battery modules were fabricated in a similar manner to Example 1 except that the thickness t₁ of the first metal layer and the thickness t₂ of the upper portion sealing layer were changed to the value shown in the following Table 1 in the solar battery module according to Example 1, and the impact resistance was tested.

As shown in Table 1, in the solar battery modules according to Examples 3 to 6, the relationship of the above-described Formula (3) is satisfied.

### Comparative Examples 2 and 3

A solar battery modules were fabricated in a similar manner to Example 1 except that the thickness t₁ of the first metal layer and the thickness t₂ of the upper portion sealing layer were changed to the value shown in the following Table 1 in the solar battery module according to Example 1, and the impact resistance was tested.

As shown in Table 1, in the solar battery modules according to Comparative Examples 2 and 3, the relationship of the above-described Formula (3) is not satisfied.

[Evaluation]

—Impact Resistance (Steel Ball Drop Test)—

The solar battery modules according to Examples 3 to 6 and Comparative Examples 2 and 3 were subjected to a steel ball drop test in a similar manner to the solar battery modules according to Examples 1 and 2 and Comparative Example 1 described above. The conditions and evaluation criteria of the steel ball drop test are similar to those described above.

The results are shown in Table 1.

TABLE 1

| | | | | | Comparative | Comparative |
|---|---|---|---|---|---|---|
| | Example 3 | Example 4 | Example 5 | Example 6 | Example 2 | Example 3 |
| Thickness of | 0.6 | 0.6 | 0.3 | 0.3 | 0.6 | 0.3 |
| first metal | | | | | | |
| layer t₁ (mm) | | | | | | |
| Thickness of | 1.2 | 0.8 | 2.0 | 1.6 | 0.4 | 0.3 |
| upper portion | | | | | | |
| sealing layer t₂ | | | | | | |
| (mm) | | | | | | |
| Right side of | 0.8 | 0.8 | 1.43495 | 1.43495 | 0.8 | 1.43495 |
| Formula (3) | | | | | | |
| Relationship | Satisfied | Satisfied | Satisfied | Satisfied | Not satisfied | Not satisfied |
| of Formula (3) | | | | | | |
| satisfied or not | | | | | | |
| Impact resistance | Qualified | Qualified | Qualified | Qualified | Disqualified | Disqualified |

As shown in Table 1, in the solar battery modules according to Examples 3 to 6 that satisfied the relational expression of Formula (3), the impact resistance to falling objects was excellent, and the damage of the solar battery cell was suppressed. On the other hand, in the solar battery modules according to Comparative Examples 2 and 3 that do not satisfy the relational expression of Formula (3), the impact resistance against falling objects was insufficient.

Therefore, as a result of the FEM calculation, it was shown that a solar battery module predicted to have excellent impact resistance against falling objects actually exhibits the effect.

The disclosure of Japanese Patent Application No. 2015-252430 filed on Dec. 24, 2015 is hereby incorporated by reference in its entirety.

All documents, patent applications, and technical standards described in this specification are incorporated herein by reference to the same extent as if each individual document, patent application, and technical specification is specifically and individually indicated to be incorporated by reference.

### DESCRIPTION OF SYMBOLS

1, 11 surface layer
2, 12 solar battery cell
3 upper portion sealing layer
4 lower portion sealing layer
5, 15 sealing layer
6 first metal layer
7 foamed layer
8 second metal layer
9 honeycomb structure (pillar structure)
10, 120 module before lamination
16 metal layer
21 hot plate
20, 30, 40 back layer
100, 200 solar battery module

1. A solar battery module including:
a solar battery cell;
a surface layer that is disposed on a sunlight incident side of the solar battery module and is made of a resin;
a sealing layer that is disposed on a side opposite to the sunlight incident side and that seals the solar battery cell, the sealing layer having, in a thickness direction, an upper portion sealing layer that seals an upper portion of the solar battery cell, which is on the sunlight incident side, and a lower portion sealing layer that seals a lower portion of the solar battery cell; and
a back layer that is disposed on a side opposite to the side on which the surface layer and the sealing layer are disposed, and that has a first metal layer made of a metal having a linear expansion coefficient lower than that of the resin constituting the surface layer, a foamed layer made of a foamed resin, and a second metal layer disposed on a side opposite to the side on which the sealing layer and the first metal layer are disposed in such a manner to sandwich the foamed layer together with the first metal layer, the second metal layer being made of a metal having a linear expansion coefficient lower than that of the resin constituting the surface layer, wherein:
a Young's modulus of an upper portion sealing material constituting the upper portion sealing layer is from 5 MPa to 20 MPa, and a Young's modulus of a lower portion sealing material constituting the lower portion sealing layer is 100 MPa or more, and
a thickness t₁ (unit: mm, t₁≥0.15) of the first metal layer and a thickness t₂ (unit: mm, t₂≥0.5) of the upper portion sealing layer satisfy the relationships of the following Formulas (1) to (5):
t₂≥2.3(t₁=0.15) (1)
t₂≥22.333t₁²−15.817t₁+4.17(0.15<t₁<0.3) (2)
t₂≥−2.1165t₁+2.0699(0.3≤t₁≤0.7) (3)
t₂≥−0.5t₁+0.95(0.7<t₁<0.9) (4)
t₂=0.5(t₁≥0.9) (5).

2. The solar battery module according to claim 1, wherein the foamed resin constituting the foamed layer is at least one resin selected from the group consisting of a polypropylene resin, an acrylic resin, an acrylonitrile-butadiene-styrene copolymer resin, and a polyacetal resin.

3. The solar battery module according to claim 1, wherein an expansion ratio of the foamed resin constituting the foamed layer is five times or less.

4. The solar battery module according to claim 1, wherein:
the resin constituting the surface layer is a polycarbonate resin, and
the metal constituting the first metal layer and the second metal layer is aluminum, an aluminum alloy, iron, or an iron alloy.

5. The solar battery module according to claim 1, wherein a pillar structure covering at least a part of an outer peripheral end portion of the foamed layer is disposed.

6. The solar battery module according to claim 2, wherein an expansion ratio of the foamed resin constituting the foamed layer is five times or less.

7. The solar battery module according to claim 2, wherein:
the resin constituting the surface layer is a polycarbonate resin, and
the metal constituting the first metal layer and the second metal layer is aluminum, an aluminum alloy, iron, or an iron alloy.

8. The solar battery module according to claim 3, wherein:
the resin constituting the surface layer is a polycarbonate resin, and
the metal constituting the first metal layer and the second metal layer is aluminum, an aluminum alloy, iron, or an iron alloy.

9. The solar battery module according to claim 2, wherein a pillar structure covering at least a part of an outer peripheral end portion of the foamed layer is disposed.

10. The solar battery module according to claim 3, wherein a pillar structure covering at least a part of an outer peripheral end portion of the foamed layer is disposed.

11. The solar battery module according to claim 4, wherein a pillar structure covering at least a part of an outer peripheral end portion of the foamed layer is disposed.

12. The solar battery module according to claim 2, wherein:
an expansion ratio of the foamed resin constituting the foamed layer is five times or less,
the resin constituting the surface layer is a polycarbonate resin, and
the metal constituting the first metal layer and the second metal layer is aluminum, an aluminum alloy, iron, or an iron alloy.

13. The solar battery module according to claim 2, wherein:
an expansion ratio of the foamed resin constituting the foamed layer is five times or less, and
a pillar structure covering at least a part of an outer peripheral end portion of the foamed layer is disposed.

14. The solar battery module according to claim 2, wherein:
the resin constituting the surface layer is a polycarbonate resin,
the metal constituting the first metal layer and the second metal layer is aluminum, an aluminum alloy, iron, or an iron alloy, and
a pillar structure covering at least a part of an outer peripheral end portion of the foamed layer is disposed.

15. The solar battery module according to claim 3, wherein:
the resin constituting the surface layer is a polycarbonate resin,
the metal constituting the first metal layer and the second metal layer is aluminum, an aluminum alloy, iron, or an iron alloy, and
a pillar structure covering at least a part of an outer peripheral end portion of the foamed layer is disposed.

16. The solar battery module according to claim 2, wherein:
an expansion ratio of the foamed resin constituting the foamed layer is five times or less,
the resin constituting the surface layer is a polycarbonate resin,
the metal constituting the first metal layer and the second metal layer is aluminum, an aluminum alloy, iron, or an iron alloy, and
a pillar structure covering at least a part of an outer peripheral end portion of the foamed layer is disposed.
